(19) United States
(12) Patent Application Publication
(10) Pub. No.: US 2025/0275445 A1
(43) Pub. Date: Aug. 28, 2025

(54) DISPLAY DEVICE

(71) Applicant: LG Display Co., Ltd., Seoul (KR)

(72) Inventors: SEONG-IL KIM, Paju-si (KR); HYUN-WOO JEON, Paju-si (KR); YOUNG-MIN OH, Paju-si (KR)

(73) Assignee: LG Display Co., Ltd., Seoul (KR)

(21) Appl. No.: 18/946,552

(22) Filed: Nov. 13, 2024

(30) Foreign Application Priority Data
Feb. 22, 2024 (KR) 10-2024-0025749

(51) Int. Cl. H10K 59/80; C09K 19/38; G02F 1/1335; G02F 1/19; H10K 59/50

(52) U.S. Cl. CPC H10K 59/8791; C09K 19/38; G02F 1/133553; G02F 1/19; H10K 59/50

(57) ABSTRACT

A display device can include a display panel, and a switchable reflective layer having an electrode layer and an electroactive material pattern and positioned at a side of the display panel. In a first mode in the electrode layer, the electroactive material pattern has a first thickness, a first width and a first pitch. In a second mode in the electrode layer, the electroactive material pattern has a second thickness, a second width and a second pitch. The electroactive material pattern satisfies at least one of i) the second thickness being different from the first thickness, ii) the second width being different from the first width, and iii) the second pitch being different from the first pitch.

### CROSS-REFERENCE TO RELATED APPLICATIONS

The present application claims priority to Korean Patent Application No. 10-2024-0025749, filed in the Republic of Korea on Feb. 22, 2024, the entire contents of which is hereby expressly incorporated by reference into the present application.

### BACKGROUND

### Technical Field

The present disclosure relates to a display device, and more particularly, to a display device being capable of controlling an ambient light reflection.

### Discussion of the Related Art

As information technology and mobile communication technology have been developed, a display device being capable of displaying a visual image has also been developed. Flat panel display devices, such as a liquid crystal display (LCD) device, a plasma display panel device (PDP) and an organic light emitting display (OLED) device, are developed and used.

In general, an LCD device includes a liquid crystal panel, which includes upper and lower substrates and a liquid crystal layer therebetween. The liquid crystal layer is driven by an electric field induced between a pixel electrode and a common electrode to display images.

An OLED device includes an organic emitting diode which includes an anode, a cathode and an organic emitting layer therebetween. In the organic emitting diode, holes and electrodes respectively from the anode and the cathode are combined such that light is emitted from the organic emitting layer to display images.

Recently, a display device is widely used in vehicles, but the internal design of the vehicle and the external design of the display device may not be harmonized with each other. Accordingly, there can be a problem of visual quality deterioration.

### SUMMARY OF THE DISCLOSURE

Accordingly, embodiments of the present disclosure are directed to a display device that substantially obviates one or more of the problems associated with the limitations and disadvantages of the related art.

An object of the present disclosure is to provide a display device being capable of controlling an ambient light reflection to improve harmony between the internal design of the vehicle and the external design of the display device.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is a display device comprising a display panel; and a switchable reflective layer including an electrode layer and an electroactive material pattern and positioned at a side of the display panel, wherein in a first mode in the electrode layer, the electroactive material pattern has a first thickness, a first width and a first pitch, wherein in a second mode in the electrode layer, the electroactive material pattern has a second thickness, a second width and a second pitch, and wherein the electroactive material pattern satisfies at least one of i) the second thickness being different from the first thickness, ii) the second width being different from the first width, and iii) the second pitch being different from the first pitch.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic cross-sectional view of a display device according to a first embodiment of the present disclosure.

FIGS. 2A and 2B are pictures showing the display device according to the first embodiment with on and off states, respectively.

FIG. 3 is schematic cross-sectional view of a display device according to a second embodiment of the present disclosure.

FIG. 4A is a schematic circuit diagram of an organic light emitting diode panel according to aspects of the present disclosure.

FIG. 4B is a schematic cross-sectional view of an organic light emitting diode panel according to aspects of the present disclosure.

FIG. 5 is a schematic cross-sectional view of a liquid crystal panel according to aspects of the present disclosure.

FIGS. 6A and 6B are schematic plane views of an electrode layer of a switchable reflective layer, respectively.

FIGS. 7A and 7B are schematic cross-sectional views illustrating a shape change of an electroactive material of a switchable reflective layer according to an applied voltage.

FIG. 8 is a schematic plane view showing an electroactive material pattern of a switchable reflective layer.

FIGS. 9A and 9B are graphs showing reflection and transmittance of a visible ray in a switchable reflective layer.

FIG. 10 is a schematic plane view showing an electroactive material pattern of a switchable reflective layer.

FIGS. 11A and 11B are graphs showing reflection and transmittance of a visible ray in a switchable reflective layer.

FIGS. 12A and 12B are graphs showing reflection and transmittance of a visible ray in a switchable reflective layer.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the disclosure and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the disclosure. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this disclosure, other parts can be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship. Further, the term “can” fully encompasses all the meanings and coverages of the term “may.”

Reference will now be made in detail to some of the examples and embodiments, which are illustrated in the accompanying drawings. All the components of each display device according to all embodiments of the present disclosure are operatively coupled and configured.

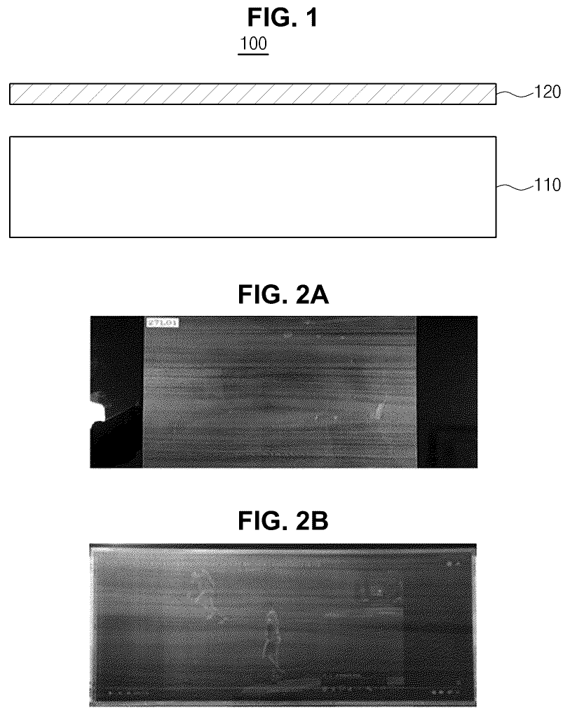

FIG. 1 is a schematic cross-sectional view of a display device according to a first embodiment of the present disclosure.

As shown in FIG. 1, a display device 100 of the present disclosure includes a display panel 110 and a colored film 120.

For example, the display panel 110 can be an organic light emitting diode panel or a liquid crystal panel.

The colored film 120 is disposed over a display surface of the display panel 110. For example, the colored film 120 has a specific color to form the external appearance of the display device 100.

Referring to FIG. 2A, which is a picture showing the display device according to the first embodiment with on state, the display device 100 has a specific color by the colored film 120 has a specific color so that the display device 100 and the design of the surrounding space can be harmonized with each other.

However, Referring to FIG. 2B, which is a picture showing the display device according to the first embodiment with off state, there are problems of low luminance and image distortion in the display device 100 by the colored film 120.

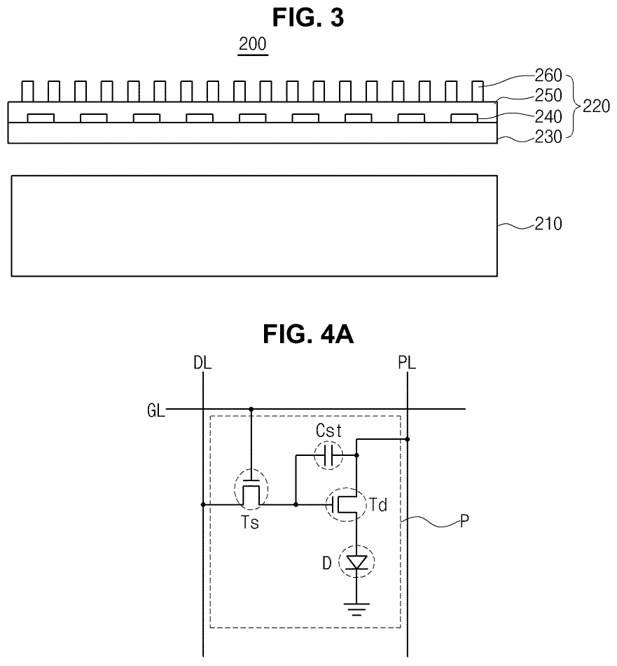

FIG. 3 is schematic cross-sectional view of a display device according to a second embodiment of the present disclosure.

As shown in FIG. 3, a display device 200 includes a display panel 210 and a switchable reflective layer 220 including an electrode layer 240 and an electroactive material pattern 260 and positioned at a side of the display panel 210.

The display panel 210 is disposed under the electrode layer 240 and displays an image.

In an aspect of the present disclosure, the display panel 210 can be an organic light emitting diode panel.

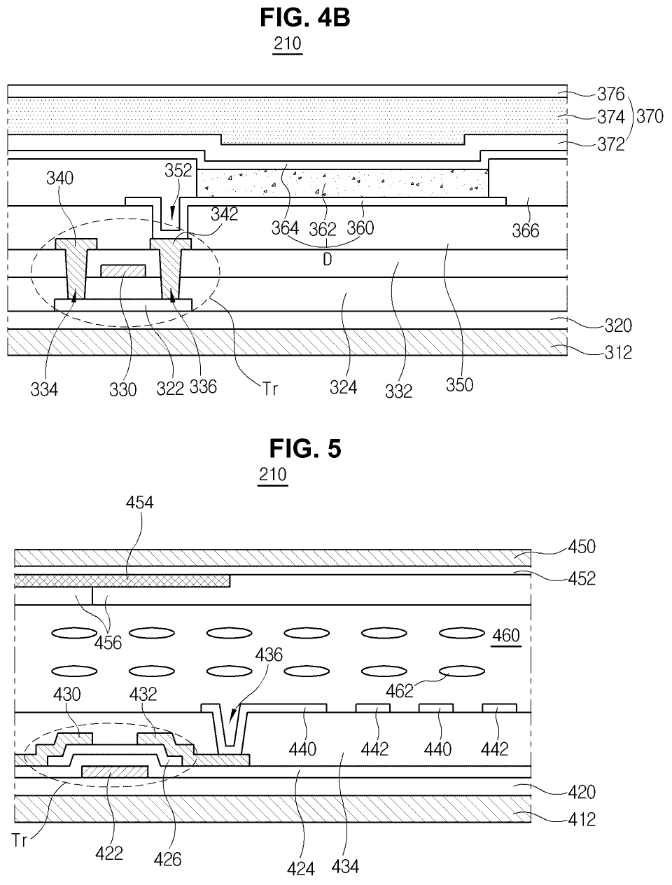

Referring to FIG. 4A, which is a schematic circuit diagram of an organic light emitting diode panel of the present disclosure, in the organic light emitting diode panel, a gate line GL and a data line DL, which can cross each other to define a pixel region P, and a power line PL can be formed in an organic light display device. A switching thin film transistor (TFT) Ts, a driving thin film transistor (TFT) Td, a storage capacitor Cst, and an OLED D can be formed in the pixel region P. The pixel region P can include a red pixel region, a green pixel region, and a blue pixel region.

The switching thin film transistor Ts can be connected to the gate line GL and the data line DL, and the driving thin film transistor Td and the storage capacitor Cst can be connected between the switching thin film transistor Ts and the power line PL. The OLED D can be connected to the driving thin film transistor Td. When the switching thin film transistor Ts is turned on by the gate signal applied through the gate line GL, the data signal applied through the data line DL can be applied to a gate electrode of the driving thin film transistor Td and one electrode of the storage capacitor Cst through the switching thin film transistor Ts.

The driving thin film transistor Td can be turned on by the data signal applied to the gate electrode so that a current proportional to the data signal can be supplied from the power line PL to the OLED D through the driving thin film transistor Td. The OLED D can emit light having a luminance proportional to the current flowing through the driving thin film transistor Td. In this case, the storage capacitor Cst can be charged with a voltage proportional to the data signal so that the voltage of the gate electrode in the driving thin film transistor Td can be kept constant or similar during one frame. Therefore, the organic light emitting display device can display a desired image.

Referring to FIG. 4B, which is a schematic cross-sectional view of an organic light emitting diode panel of the present disclosure, the organic light emitting diode panel 210 can include a substrate 312, a TFT Tr over the substrate 312, a planarization layer 350 covering the TFT Tr and an OLED D disposed on the planarization layer 350 and connected to the TFT Tr. For example, the organic light emitting diode panel 210 can include a red pixel region, a green pixel region, and a blue pixel region.

The substrate 312 can be a glass substrate or a flexible substrate. For example, the flexible substrate can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 320 can be formed on the substrate, and the TFT Tr can be formed on the buffer layer 320. The buffer layer 320 can be omitted. The buffer layer 320 can be formed of an inorganic insulating material, e.g., silicon oxide or silicon nitride.

A semiconductor layer 322 can be formed on the buffer layer 320. The semiconductor layer 322 can include an oxide semiconductor material or polycrystalline silicon.

When the semiconductor layer 322 includes the oxide semiconductor material, a light-shielding pattern can be formed under the semiconductor layer 322. The light to the semiconductor layer 322 can be shielded or blocked by the light-shielding pattern such that thermal degradation of the semiconductor layer 322 can be prevented or reduced. On the other hand, when the semiconductor layer 322 includes polycrystalline silicon, impurities can be doped into both sides of the semiconductor layer 322.

A gate insulating layer 324 can be formed on the semiconductor layer 322. The gate insulating layer 324 can be formed of an inorganic insulating material such as silicon oxide or silicon nitride.

A gate electrode 330, which can be formed of a conductive material, e.g., metal, can be formed on the gate insulating layer 324 to correspond to a center of the semiconductor layer 322.

In FIG. 4B, the gate insulating layer 324 can be formed on an entire surface of the substrate 312. Alternatively, the gate insulating layer 324 can be patterned to have the same shape as the gate electrode 330.

An interlayer insulating layer 332, which can be formed of an insulating material, can be formed on the gate electrode 330. The interlayer insulating layer 332 can be formed of an inorganic insulating material, e.g., silicon oxide or silicon nitride, or an organic insulating material, e.g., benzocyclobutene or photo-acryl.

The interlayer insulating layer 332 can include first and second contact holes 334 and 336 exposing both sides of the semiconductor layer 322. The first and second contact holes 334 and 336 may not cover a portion of the surface of the semiconductor layer 322 that is nearer to the opposing ends than to a center of the semiconductor layer 322. The first and second contact holes 334 and 336 can be positioned at both sides of the gate electrode 330 to be spaced apart from the gate electrode 330. In FIG. 4B, the first and second contact holes 334 and 336 can be formed through the interlayer insulating layer 332 and the gate insulating layer 324. Alternatively, when the gate insulating layer 324 is patterned to have the same shape as the gate electrode 330, the first and second contact holes 334 and 336 can be formed only through the interlayer insulating layer 332.

A source electrode 340 and a drain electrode 342, which can be formed of a conductive material, e.g., metal, can be formed on the interlayer insulating layer 332. The source electrode 340 and the drain electrode 342 can be spaced apart from each other with respect to the gate electrode 330 and can contact both sides of the semiconductor layer 322 through the first and second contact holes 334 and 336, respectively.

The semiconductor layer 322, the gate electrode 330, the source electrode 340, and the drain electrode 342 can constitute the TFT Tr. The TFT Tr can serve as a driving element. For example, the TFT Tr can correspond to the driving TFT Td (of FIG. 4A).

In the TFT Tr, the gate electrode 330, the source electrode 340, and the drain electrode 342 can be positioned on the semiconductor layer 322. For example, the TFT Tr can have a coplanar structure.

Alternatively, in the TFT Tr, the gate electrode can be positioned under the semiconductor layer, and the source and drain electrodes can be positioned on the semiconductor layer such that the TFT Tr can have an inverted staggered structure. In this instance, the semiconductor layer can include amorphous silicon.

The gate line and the data line can cross each other to define the pixel region, and the switching TFT can be formed to be connected to the gate and data lines. The switching TFT can be connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer (or a passivation layer) 350 can be formed to cover the TFT Tr. The planarization layer 350 can provide a flat top surface and includes a drain contact hole 352 exposing the drain electrode 342 of the TFT Tr. The planarization layer 350 can be formed of an inorganic insulating material, e.g., silicon oxide or silicon nitride, or an organic insulating material, e.g., benzocyclobutene or photo-acryl.

The OLED D is disposed on the planarization layer 350 and includes a first electrode 360, which is connected to the drain electrode 342 of the TFT Tr, an organic light emitting layer 362 on the first electrode 360 and a second electrode 364 on the organic light emitting layer 362. The OLED D is positioned in each of the red, green and blue pixel regions and emits red, green and blue light at the red, green and blue pixel regions, respectively.

The first electrode 360 can be separately formed in each pixel region. The first electrode 360 can be an anode and can include a transparent conductive oxide material layer formed of a conductive material, e.g., a transparent conductive oxide (TCO), having a relatively high work function. For example, the transparent conductive oxide material layer of the first electrode 360 can include at least one of indium-tin-oxide (ITO) indium-zinc-oxide (IZO), indium-tin-zinc oxide; ITZO), tin oxide (SnO), zinc oxide (ZnO), indium-copper-oxide (ICO) and Al:ZnO (AZO).

The first electrode 360 can have a single-layered structure of the transparent conductive oxide material layer. Namely, the first electrode 360 can be a transparent electrode.

Alternatively, the first electrode 360 can further include a reflection layer to have a double-layered structure or a triple-layered structure. Namely, the first electrode 360 can be a reflection electrode.

For example, the reflection layer can be formed of silver (Ag), an alloy of Ag with at least one of palladium (Pd), copper (Cu), indium (In) and neodymium (Nd) or aluminum-palladium-copper (APC) alloy. In an aspect of the present disclosure, the first electrode 360 can have a double-layered structure of Ag/ITO or APC/ITO or a triple-layered structure of ITO/Ag/ITO or ITO/APC/ITO. However, embodiments of the present disclosure are not limited to such examples.

A bank layer 366 can be formed on the planarization layer 350 to cover an edge of the first electrode 360. For example, the bank layer 366 can be positioned at a boundary of the pixel region and exposes a center of the first electrode 360 in the pixel region.

The organic light emitting layer 362 including an emitting material layer (EML) is formed on the first electrode 360. The organic light emitting layer 362 can have a multi-layered structure including at least one of a hole injection layer (HIL), a hole transporting layer (HTL), an electron blocking layer (EBL), a hole blocking layer (HBL), an electron transporting layer (ETL), and an electron injection layer (EIL).

In an aspect of the present disclosure, the organic light emitting layer 362 can emit red, green and blue light at the red, green and blue pixel regions, respectively. Alternatively, the organic light emitting layer 362 can emit white light at the red, green and blue pixel regions.

A second electrode 364 is formed over the substrate 312 where the organic light emitting layer 362 is formed. The second electrode 364 can cover an entire surface of the display area and can be formed of a conductive material having a relatively low work function to serve as a cathode. For example, the second electrode 364 can be formed of aluminum (Al), magnesium (Mg), calcium (Ca), silver (Ag) or their alloy, e.g., MgAg, or a combination thereof.

In the top-emission type organic light emitting diode panel 210, the first electrode 360 is a reflection electrode, and the second electrode 364 has a thin profile (small thickness) to provide a light transmittance property (or a semi-transmittance property). In the bottom-emission type organic light emitting diode panel 210, the first electrode 360 is a transparent electrode, and the second electrode 364 is a reflection electrode.

In the top-emission type organic light emitting diode panel 210, a capping layer can be further formed on the second electrode 364. The optical efficiency of the organic light emitting diode panel 210 can be further improved by the capping layer.

An encapsulation layer (e.g., an encapsulation film) 370 can be formed on the second electrode 364 to prevent penetration of moisture into the OLED D. The encapsulation layer 370 can include a first inorganic insulating layer 372, an organic insulating layer 374, and a second inorganic insulating layer 376 sequentially stacked. However, embodiments of the present disclosure are not limited to such examples. The encapsulation layer 370 can be omitted.

In the bottom-emission type organic light emitting diode panel 210, a metal encapsulation plate can be further disposed on the second electrode 364 or the encapsulation layer 370. For example, metal encapsulation plate can be attached onto the second electrode 364 or the encapsulation layer 370 using an adhesive layer.

The organic light emitting diode panel 210 can further include a color filter layer corresponding to the red, green and blue pixel regions. In the top-emission type organic light emitting diode panel 210, the color filter layer can be positioned over the OLED D, e.g., over the second electrode 364 or the encapsulation layer 370. In the bottom-emission type organic light emitting diode panel 210, the color filter layer can be positioned between the OLED D and the substrate 312, e.g., between the interlayer insulating layer 332 and the planarization layer 350.

The color filter layer can include red, green and blue color filter patterns respectively corresponding to the red, green and blue pixel regions. The red color filter pattern can include at least one of a red dye and a red pigment, the green color filter pattern can include at least one of a green dye and a green pigment, and the blue color filter pattern can include at least one of a blue dye and a blue pigment.

The organic light emitting diode panel 210 can further include a polarization plate for reducing an ambient light reflection. For example, the polarization plate can be a circular polarization plate. In the bottom-emission type organic light emitting diode panel 210, the polarization plate can be disposed under the substrate 312. In the top-emission type organic light emitting diode panel 210, the polarization plate can be disposed on or over the encapsulation layer 370.

In an aspect of the present disclosure, the display panel 210 can be a liquid crystal panel.

Referring to FIG. 5, which is a schematic cross-sectional view of a liquid crystal panel of the present disclosure, the liquid crystal panel 210 includes first and second substrates 412 and 450, which face each other, and a liquid crystal layer 460, which includes liquid crystal molecules 462, therebetween.

Each of the first and second substrates 412 and 450 can be a glass substrate or a flexible substrate. For example, the flexible substrate can be one of polyimide (PI) substrate, polyethersulfone (PES) substrate, polyethylenenaphthalate (PEN) substrate, polyethylene terephthalate (PET) substrate and polycarbonate (PC) substrate.

A first buffer layer 420 is formed on the first substrate 412, and a TFT Tr is formed on the first substrate 412. The first buffer layer 420 can be omitted. The first buffer layer 420 can be formed of an inorganic insulating material, e.g., silicon oxide or silicon nitride.

A gate electrode 422 is formed on the first buffer layer 420, and a gate insulating layer 424 is formed on the gate electrode 422. In addition, a gate line, which is connected to the gate electrode 422, is formed on the first buffer layer 420.

A semiconductor layer 426, which corresponds to the gate electrode 422, is formed on the gate insulating layer 424. The semiconductor layer 426 can include an oxide semiconductor material. Alternatively, the semiconductor layer can include an active layer of intrinsic amorphous silicon and an ohmic contact layer of impurity-doped amorphous silicon.

A source electrode 430 and a drain electrode 432, which are spaced apart from each other, are formed on the semiconductor layer 426. In addition, a data line, which is electrically connected to the source electrode 430 and crosses the gate line to define a pixel region, is formed.

The gate electrode 422, the semiconductor layer 426, the source electrode 430 and the drain electrode 432 constitute the TFT Tr.

A planarization layer 434, which includes a drain contact hole 436 exposing the drain electrode 432, is formed on the TFT Tr. The planarization layer 434 can be formed of an inorganic insulating material, e.g., silicon oxide or silicon nitride, or an organic insulating material, e.g., benzocyclobutene or photo-acryl.

A pixel electrode 440, which is connected to the drain electrode 432 through the drain contact hole 436, and a common electrode 442, which is alternately arranged with the pixel electrode 440, are formed on the planarization layer 434.

Each of the pixel electrode 440 and the common electrode 442 can be formed of a transparent conductive material. For example, each of the pixel electrode 440 and the common electrode 442 can be formed of one of indium-tin-oxide (ITO) indium-zinc-oxide (IZO), indium-tin-zinc oxide; ITZO), tin oxide (SnO), zinc oxide (ZnO), indium-copper-oxide (ICO) and Al:ZnO (AZO).

A second buffer layer 452 is formed on the second substrate 450. The second buffer layer 452 can be formed of an inorganic insulating material, e.g., silicon oxide or silicon nitride.

A black matrix 454, which shields a non-display region such as the TFT Tr, the gate line and the data line, is formed on the second buffer layer 452. In addition, a color filter layer 456, which corresponds to the pixel region, is formed on the second buffer layer 452. The second buffer layer 452 and the black matrix 454 can be omitted.

The display panel 210 can include red, green and blue pixel regions, and the color filter layer 456 can include red, green and blue color filter patterns respectively corresponding to the red, green and blue pixel regions. The red color filter pattern can include at least one of red dye and red pigment. The green color filter pattern can include at least one of green dye and green pigment. The blue color filter pattern can include at least one of blue dye and blue pigment.

The first and second substrates 412 and 450 are attached with the liquid crystal layer 460 therebetween. The liquid crystal molecules 462 of the liquid crystal layer 460 is driven by an electric field between the pixel and common electrode 440 and 442.

In FIG. 5, the pixel electrode 440 and the common electrode 442 are disposed on the same layer, i.e., on the planarization layer 434. Alternatively, the pixel electrode 440 and the common electrode 442 can be disposed at different layers. For example, the common electrode 442 can be disposed on the second electrode 450.

First and second alignment layers can be formed over the first and second substrates 412 and 450 to be adjacent to the liquid crystal layer 460. In addition, first and second polarization plates, which have perpendicular transmission axes, can be attached to an outer side of each of the first and second substrates 412 and 450. Moreover, the liquid crystal panel 210 can further include a backlight unit under the first substrate 412. For example, the backlight unit can include a light guide plate under the first substrate 412, a light source at a side of the light guide plate, a reflection layer under the light guide plate and an optical sheet between the light guide plate and the first substrate 412.

Referring to FIG. 3 again, the switchable reflective layer 220 is disposed at a display surface of the display panel 210.

When the display panel 210 is the top-emission type organic light emitting diode panel, the switchable reflective layer 220 can be disposed on or over the encapsulation layer 370. Alternatively, when the display panel 210 is the bottom-emission type organic light emitting diode panel, the switchable reflective layer 220 can be disposed under the substrate 312.

When the display panel 210 is the liquid crystal panel, the switchable reflective layer 220 can be disposed over the second substrate 450.

In the switchable reflective layer 220, the electrode layer 240 is positioned between the electroactive material pattern 260 and the display panel 210.

The switchable reflective layer 220 can further include a base 230 between the display panel 210 and the electrode layer 240. The base 230 provides a surface on which the electrode layer 240 is formed. The base 230 can be formed of polyethylene terephthalate (PET) or tri-acetyl cellulose (TAC).

The electrode layer 240 can be formed on the base 230. Namely, the base 230 covers the display panel 210 and is disposed under the electrode layer 240. The electrode layer 240 includes a plurality of first electrodes, which are spaced apart from each other, and a plurality of second electrodes, which are alternately arranged with the plurality of the first electrodes. Alternatively, the base 230 can be omitted, and the electrode layer 240 can be formed directly on the display panel 210.

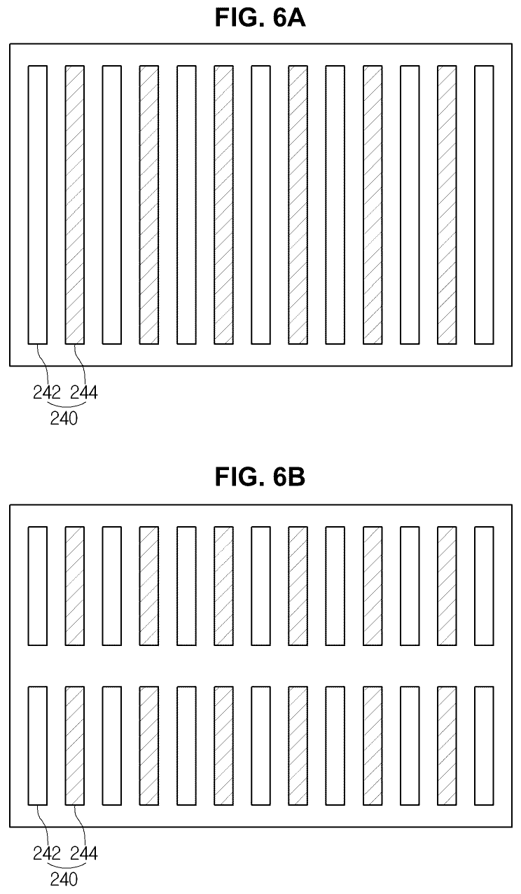

Referring to FIG. 6A, which is a schematic plane view of an electrode layer of a switchable reflective layer, the electrode layer 240 includes the plurality of first electrodes 242 and the plurality of second electrodes 244.

The first electrodes 242 and the second electrodes 244 are alternately arranged with each other on the base 230 (of FIG. 3) and along a first direction. Namely, the plurality of first electrodes 242 are arranged to be spaced apart from each other, and the plurality of second electrodes 244 are arranged between adjacent first electrodes 242 and to be spaced apart from the first electrode 242.

Each of the first electrodes 242 and the second electrodes 244 can be include or formed of a transparent conductive material. For example, each of the first electrodes 242 and the second electrodes 244 can include at least one of indium-tin-oxide (ITO) indium-zinc-oxide (IZO), indium-tin-zinc oxide; ITZO), tin oxide (SnO), zinc oxide (ZnO), indium-copper-oxide (ICO) and Al:ZnO (AZO).

Referring to FIG. 6B, which is a schematic plane view of an electrode layer of a switchable reflective layer, the electrode layer 240 can include the first electrodes 242, which are spaced apart from each other in a first direction and a second direction, and the second electrodes 244, which are spaced apart from each other in a first direction and a second direction and alternately arranged with the first electrodes 242. Each of the first electrodes 242 and the second electrodes 244 can be include or formed of a transparent conductive material.

Referring to FIG. 3 again, an insulating layer 250 is formed on the electrode layer 240 including the first and second electrodes 242 and 244. Namely, the insulating layer 250 covers the electrode layer 240 and is disposed under the electroactive material pattern 260. The insulating layer 250 planarizes a step difference by the first and second electrodes 242 and 244 and can provide a flat top surface.

The insulating layer 250 can include or formed of an inorganic insulating material, e.g., silicon oxide or silicon nitride, or an organic insulating material, e.g., benzocyclobutene or photo-acryl.

The electroactive material pattern 260 is formed on the insulating layer 250. In an aspect of the present disclosure, the insulating layer 250 can be omitted so that the electroactive material pattern 260 can be formed directly on the electrode layer 240.

A cover window covering the electroactive material pattern 260 can be disposed on the electroactive material pattern 260.

The electroactive material pattern 260 is substantially transparent, and at least one of a shape and a volume of the electroactive material pattern 260 is changed according to a voltage applied to the electrode layer 240.

For example, a cation and/or an anion can be moved in the electroactive material pattern 260 according to a voltage applied to the electrode layer 240 so that a charge and/or a size of the electroactive material pattern 260 can be changed. As a result, a length and/or a shape of the electroactive material pattern 260 can be changed. Alternatively, the electroactive material pattern 260 can absorb an ion according to a voltage applied to the electrode layer 240 so that a volume of the electroactive material pattern 260 can be changed.

In an aspect of the present disclosure, a thickness, i.e., a height, of the electroactive material pattern 260 can be changed according to a voltage applied to the electrode layer 240. In an aspect of the present disclosure, a width of the electroactive material pattern 260 can be changed according to a voltage applied to the electrode layer 240. In other words, a distance, i.e., a pitch, between adjacent electroactive material patterns 260 can be changed.

The electroactive material pattern 260 can include an electroactive material. For example, the electroactive material pattern 260 can be an electroactive polymer.

In an aspect of the present disclosure, the electroactive material pattern 260 can include at least one of poly vinylidene fluoride (PVDF), poly vinylidene cyanide (PVDCN), poly vinylidene chloride (PVDCL), polypyrrole, polyacrylonitrile, polydimethylsiloxane (PDMS), amide polymer, urea polymer and carbonyl polymer.

For example, poly vinylidene fluoride (PVDF) can be represented by one of Formulas 1-1 to 1-3, and poly vinylidene cyanide (PVDCN) can be represented by Formula 2. The poly vinylidene chloride (PVDCL) can be represented by Formula 3, and the amide polymer can be represented by one of Formulas 4-1 and 4-2. The urea polymer can be represented by one of Formulas 5-1 and 5-2, and the carbonyl polymer can be represented by one of Formulas 6-1 and 6-2.

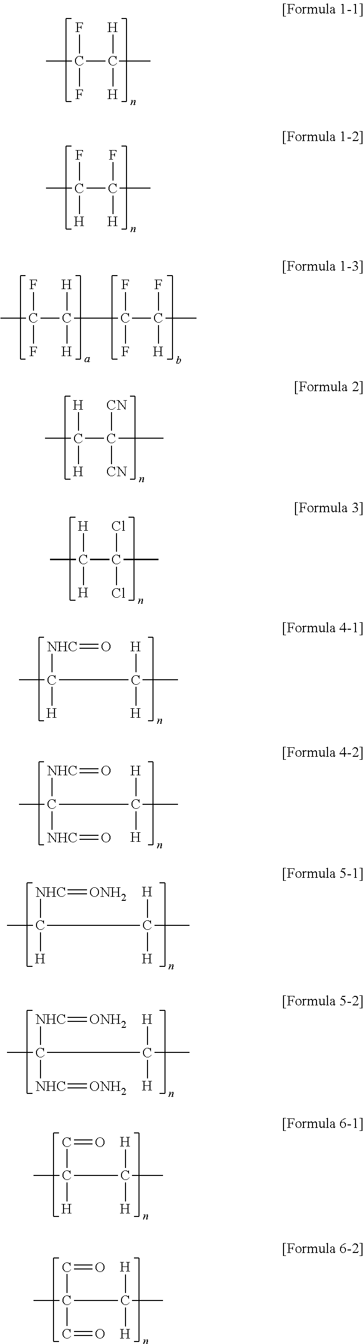

In each of Formulas 1-1, 1-2 and 2 to 6-2, n is an integer of 100 to 20000. In Formula 1-3, a is a number of 0.7 to 0.8, and b is a number of 0.2 to 0.3. Here, it can be that a+b=1. As a result, the electroactive material can have a molecular weight of about 10000 to 100000.

The electroactive material can have a dipole moment. A degree of the shape change and or the size change of the electroactive material can depend on the in the intensity of the dipole moment.

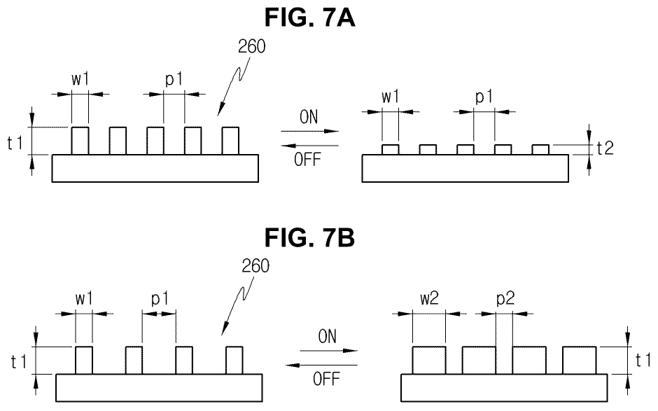

Referring to FIG. 7A, which is a schematic cross-sectional view illustrating a shape change of an electroactive material of a switchable reflective layer according to an applied voltage, with FIGS. 6A and 6B, without a voltage to the electrode layer, the electroactive material pattern 260 has a first thickness t1, a first width w1 and a first pitch p1, and with a voltage to the electrode layer, the electroactive material pattern 260 can have a second thickness t2 smaller than the first thickness t1.

Namely, when a voltage is applied to the first and second electrodes 242 and 244 of the electrode layer 240, a thickness of the electroactive material pattern 260 is decreased. Alternatively, when a voltage is applied to the first and second electrodes 242 and 244 of the electrode layer 240, a thickness of the electroactive material pattern 260 can be increased.

Referring to FIG. 7B, which is a schematic cross-sectional view illustrating a shape change of an electroactive material of a switchable reflective layer according to an applied voltage, with FIGS. 6A and 6B, without a voltage to the electrode layer, the electroactive material pattern 260 has a first thickness t1, a first width w1 and a first pitch p1, and with a voltage to the electrode layer, the electroactive material pattern 260 can have a second width w2 greater than the first width w1 and a second pitch p2 smaller than the first pitch p1.

Namely, when a voltage is applied to the first and second electrodes 242 and 244 of the electrode layer 240, a width of the electroactive material pattern 260 is increased. Alternatively, when a voltage is applied to the first and second electrodes 242 and 244 of the electrode layer 240, a width of the electroactive material pattern 260 can be decreased so that the pitch of the electroactive material pattern 260 can be increased.

When the electroactive material pattern 260 has a first thickness t1, a first width w1 and a first pitch p1, the ambient light is reflected by the electroactive material pattern 260. Accordingly, the display device 200 can have a desired design. On the other hand, when the electroactive material pattern 260 has a second thickness t2, which is smaller than the first thickness t1, and/or a second pitch p1, which is smaller than the first pitch p1, the electroactive material pattern 260 does not reflect a visible light and has high transmittance. Namely, the transmittance and the reflectance of the switchable reflective layer 220 is changed according to a voltage to the electrode layer 240.

In FIG. 7A, a thickness of the electroactive material pattern 260 is changed with constant width and pitch. In FIG. 7B, a width and a pitch of the electroactive material pattern 260 are changed with constant thickness. Alternatively, all of the thickness, the width and the pitch of the electroactive material pattern 260 can be changed according to a voltage to the electrode layer 240.

In FIGS. 7A and 7B, without a voltage to the first and second electrodes 242 and 244 of the electrode layer 240, the electroactive material pattern 260 has a first thickness t1, a first width w1 and a first pitch p1 so that a visible light is reflected by the electroactive material pattern 260.

Alternatively, without a voltage to the first and second electrodes 242 and 244 of the electrode layer 240, the visible light may not be reflected by the electroactive material pattern 260, while with a voltage to the first and second electrodes 242 and 244 of the electrode layer 240, at least one of the thickness, the width and the pitch of the electroactive material pattern 260 can be changed so that the electroactive material pattern 260 can have a first thickness t1, a first width w1 and a first pitch p1. In this case, the electroactive material pattern 260 has high transmittance without a voltage to the first and second electrodes 242 and 244 of the electrode layer 240 so that the luminance of the display device 200 is increased. On the other hand, the electroactive material pattern 260 has high reflectance with a voltage to the first and second electrodes 242 and 244 of the electrode layer 240 so that the display device 200 has a desired design.

In the display device 200 of the present disclosure, the electroactive material pattern 260 with a first mode (e.g., without a voltage difference) in the electrode layer 240 and the electroactive material pattern 260 with a second mode (e.g., with a voltage difference) in the electrode layer 240 have a difference in at least one of a thickness, a width and a pitch. In other words, the electroactive material pattern 260 without a voltage difference in the electrode layer 240 has a first thickness, a first width and a first pitch, and the electroactive material pattern 260 with a voltage difference in the electrode layer 240 has a second thickness, a second width and a second pitch. The electroactive material pattern 260 satisfies at least one of the following conditions: i) the second thickness is different from the first thickness, ii) the second width is different from the first width, and iii) the second pitch is different from the first pitch. In the first mode, the same voltage, e.g., OV, is applied to the first and second electrodes 242 and 244 (of FIGS. 6A and 6B). In the second mode, the different voltages are applied to the first and second electrodes 242 and 244.

For example, i) the second thickness is different from the first thickness and the second pitch is equal to the first pitch, and/or ii) the second thickness is equal to the first thickness and the second pitch is different from the first pitch, and/or iii) the second thickness is different from the first thickness and the second pitch is different from the first pitch.

Accordingly, the switchable reflective layer 220 without a voltage difference in the electrode layer 240 has a first reflectance and a first transmittance, and the switchable reflective layer 220 with a voltage difference in the electrode layer 240 has a second reflectance being different from the first reflectance and a second transmittance being different from the first transmittance.

In an aspect of the present disclosure, when the display panel 210 is not driven, i.e., an image non-display mode, there is no voltage difference in the electrode layer 240 so that the switchable reflective layer 220 can have high reflectance. When the display panel 210 is driven, i.e., an image display mode, there is a voltage difference in the electrode layer 240 so that the switchable reflective layer 220 can have high transmittance.

In an aspect of the present disclosure, when the display panel 210 is not driven, i.e., an image non-display mode, there is a voltage difference in the electrode layer 240 so that the switchable reflective layer 220 can have high reflectance. When the display panel 210 is driven, i.e., an image display mode, there is no voltage difference in the electrode layer 240 so that the switchable reflective layer 220 can have high transmittance.

Accordingly, the display device 200 of the present disclosure can provide excellent design without a transmittance decrease (i.e., a luminance decrease).

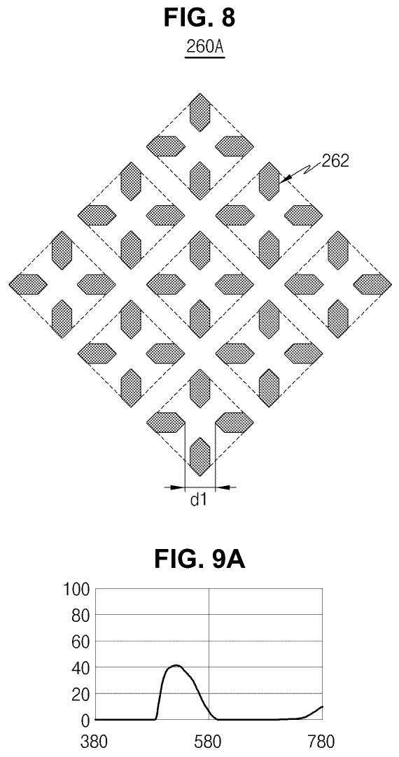

FIG. 8 is a schematic plane view showing an electroactive material pattern of a switchable reflective layer.

Referring to FIG. 8, the electroactive material pattern 260A includes a plurality of first patterns 262 positioned at a corner of a first pattern region having a rectangular shape. Each of the plurality of first patterns 262 has a hexagonal shape with a major axis and a minor axis and is spaced apart from each other by a first distance (e.g., pitch) d1. The major axis length of the first pattern 262 can be equal to or smaller than the first distance d1. In an aspect of the present disclosure, the major axis length of the first pattern 262 can be smaller than the first distance d1.

In an aspect of the present disclosure, in each of the plurality of first patterns 262, the major axis length can be in the range of 220 to 240 nm, the minor axis length can be in the range of 120 to 140 nm, and the first distance d1 can be in the range of 240 to 260 nm. In addition, each of the plurality of first patterns 262 can have a thickness equal to the first pitch d1.

FIGS. 9A and 9B are graphs showing reflection and transmittance of a visible ray in a switchable reflective layer. In FIG. 9A, the x-axis (i.e., the horizontal axis) is the wavelength, and the y-axis (i.e., the vertical axis) is the reflectance. In FIG. 9B, the x-axis (i.e., the horizontal axis) is the wavelength, and the y-axis (i.e., the vertical axis) is the transmittance.

As shown in FIG. 9A, in the switchable reflective layer 220 including the electroactive material pattern 260A, the switchable reflective layer 220 without a voltage to the electrode layer 240 has high reflectance to a visible light in the range of 500 to 550 nm. On the other hand, as shown in FIG. 9B, the switchable reflective layer 220 with a voltage to the electrode layer 240 has high transmittance to the visible light.

For example, referring to FIG. 7A, the electroactive material pattern 260A without a voltage to the electrode layer 240 has a first thickness t1, a first width w1 and a first pitch p1 so that the switchable reflective layer 220 has high reflectance to a visible light in the range of 500 to 550 nm. On the other hand, the electroactive material pattern 260A without a voltage to the electrode layer 240 has a second thickness t1 smaller than the first thickness t1 so that the reflectance of the switchable reflective layer 220 is decreased and the transmittance of the switchable reflective layer 220 is increased.

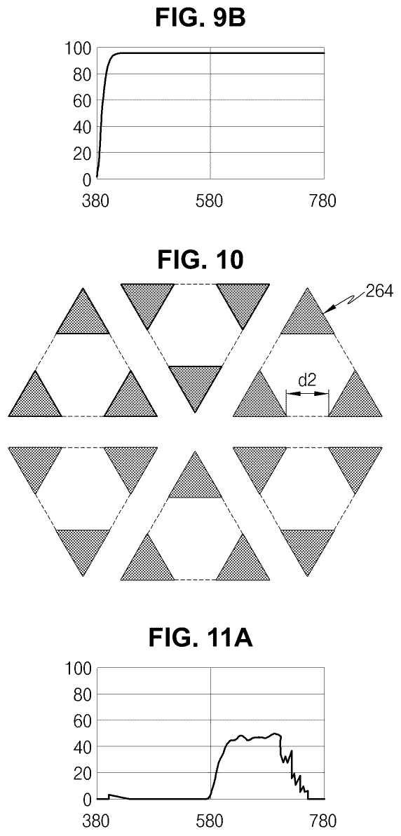

FIG. 10 is a schematic plane view showing an electroactive material pattern of a switchable reflective layer.

Referring to FIG. 10, the electroactive material pattern 260B includes a plurality of second patterns 264 positioned at a corner of a second pattern region having a triangular shape. Each of the plurality of second patterns 264 has a triangular shape and is spaced apart from each other by a second distance d2. A side length of the second pattern 264 can be equal to or smaller than the second distance d2. In an aspect of the present disclosure, the side length of the second pattern 264 can be equal to the second distance d2.

In an aspect of the present disclosure, in each of the plurality of second patterns 264, each of the side length and the second distance d2 can be in the range of 330 to 350 nm. In addition, each of the plurality of second patterns 264 can have a thickness smaller than the second distance d2. For example, each of the plurality of second patterns 264 can have a thickness of 190 to 210 nm.

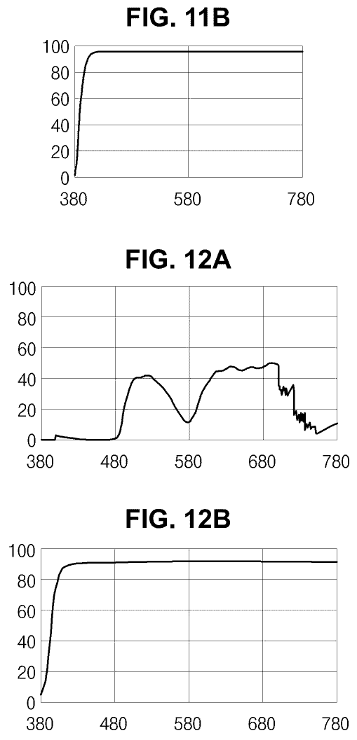

FIGS. 11A and 11B are graphs showing reflection and transmittance of a visible ray in a switchable reflective layer. In FIG. 11A, the x-axis (i.e., the horizontal axis) is the wavelength, and the y-axis (i.e., the vertical axis) is the reflectance. In FIG. 11B, the x-axis (i.e., the horizontal axis) is the wavelength, and the y-axis (i.e., the vertical axis) is the transmittance.

As shown in FIG. 11A, in the switchable reflective layer 220 including the electroactive material pattern 260B, the switchable reflective layer 220 without a voltage to the electrode layer 240 has high reflectance to a visible light in the range of 630 to 700 nm.

On the other hand, as shown in FIG. 11B, the switchable reflective layer 220 with a voltage to the electrode layer 240 has high transmittance to the visible light.

For example, referring to FIG. 7A, the electroactive material pattern 260A without a voltage to the electrode layer 240 has a first thickness t1, a first width w1 and a first pitch p1 so that the switchable reflective layer 220 has high reflectance to a visible light in the range of 500 to 550 nm. On the other hand, the electroactive material pattern 260A without a voltage to the electrode layer 240 has a second thickness t1 smaller than the first thickness t1 so that the reflectance of the switchable reflective layer 220 is decreased and the transmittance of the switchable reflective layer 220 is increased.

In an aspect of the present disclosure, the switchable reflective layer 220 can include a first region and a second region, in each of a condition without a voltage to the electrode layer 240 and a condition with a voltage to the electrode layer 240, the electroactive material pattern 260 in the first region and the electroactive material pattern 260 in the second region can have a difference in at least one of a shape, a thickness, a width and a pitch. As a result, in a condition without a voltage to the electrode layer 240 or a condition with a voltage to the electrode layer 240, a light having a first wavelength range can be reflected by the switchable reflective layer 220 in the first region, and a light having a second wavelength range, which is different from the first wavelength range, can be reflected by the switchable reflective layer 220 in the second region.

For example, referring to FIGS. 8 and 10, the first pattern region including the first patterns 262 can be arranged in the first region of the switchable reflective layer 220, and the second pattern region including the second patterns 264 can be arranged in the second region of the switchable reflective layer 220.

FIGS. 12A and 12B are graphs showing reflection and transmittance of a visible ray in a switchable reflective layer. In FIG. 12A, the x-axis (i.e., the horizontal axis) is the wavelength, and the y-axis (i.e., the vertical axis) is the reflectance. In FIG. 12B, the x-axis (i.e., the horizontal axis) is the wavelength, and the y-axis (i.e., the vertical axis) is the transmittance.

As shown in FIG. 12A, the switchable reflective layer 220 without a voltage to the electrode layer 240 has high reflectance to a visible light in the range of 500 to 550 nm and the range of 630 to 730 nm. On the other hand, as shown in FIG. 12B, the switchable reflective layer 220 with a voltage to the electrode layer 240 has high transmittance to the visible light.

As described above, the display device 200 of the present disclosure includes a display panel 210 and a switchable reflective layer 220 including an electrode layer 240 and an electroactive material pattern 260 and positioned at a side, i.e., a display side, of the display panel 210. At least one of a thickness and a pitch of the electroactive material pattern 260 is changed according to a voltage to the electrode layer 240. Accordingly, the switchable reflective layer 220 has a first reflectance and a first transmittance in a first mode and a second reflectance, which is smaller than the first reflectance, and a second transmittance, which is smaller than the first transmittance, in a second mode so that the display device 200 can have a desired design without the luminance decrease.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. A display device, comprising:
a display panel; and
a switchable reflective layer including an electrode layer and an electroactive material pattern and positioned at a side of the display panel,
wherein in a first mode in the electrode layer, the electroactive material pattern has a first thickness, a first width and a first pitch,
wherein in a second mode in the electrode layer, the electroactive material pattern has a second thickness, a second width and a second pitch, and
wherein the electroactive material pattern satisfies at least one of i) the second thickness being different from the first thickness, ii) the second width being different from the first width, and iii) the second pitch being different from the first pitch.

2. The display device according to claim 1, wherein in the first mode in the electrode layer, the switchable reflective layer has a first reflectance and a first transmittance, and
wherein in the second mode in the electrode layer, the switchable reflective layer has a second reflectance being smaller than the first reflectance and a second transmittance being greater than the first transmittance.

3. The display device according to claim 2, wherein in the first mode in the electrode layer, the display panel is not driven, and
wherein in the second mode in the electrode layer, the display panel is driven.

4. The display device according to claim 2, wherein the second thickness is smaller than the first thickness.

5. The display device according to claim 2, wherein the second pitch is smaller than the first pitch.

6. The display device according to claim 1, wherein in the first mode in the electrode layer, the switchable reflective layer has a first reflectance and a first transmittance, and
wherein in the second mode in the electrode layer, the switchable reflective layer has a second reflectance being greater than the first reflectance and a second transmittance being smaller than the first transmittance.

7. The display device according to claim 6, wherein in the first mode in the electrode layer, the display panel is driven, and
wherein in the second mode in the electrode layer, the display panel is not driven.

8. The display device according to claim 6, wherein the second thickness is greater than the first thickness.

9. The display device according to claim 6, wherein the second pitch is greater than the first pitch.

10. The display device according to claim 1, wherein the electroactive material pattern includes at least one of poly vinylidene fluoride (PVDF), poly vinylidene cyanide (PVDCN), poly vinylidene chloride (PVDCL), polypyrrole, polyacrylonitrile, polydimethylsiloxane (PDMS), amide polymer, urea polymer and carbonyl polymer.

11. The display device according to claim 1, wherein the electroactive material pattern includes a material represented by one of Formulas 1-1 to 1-3, 2, 3, 4-1, 4-2, 5-1, 5-2, 6-1 and 6-2: 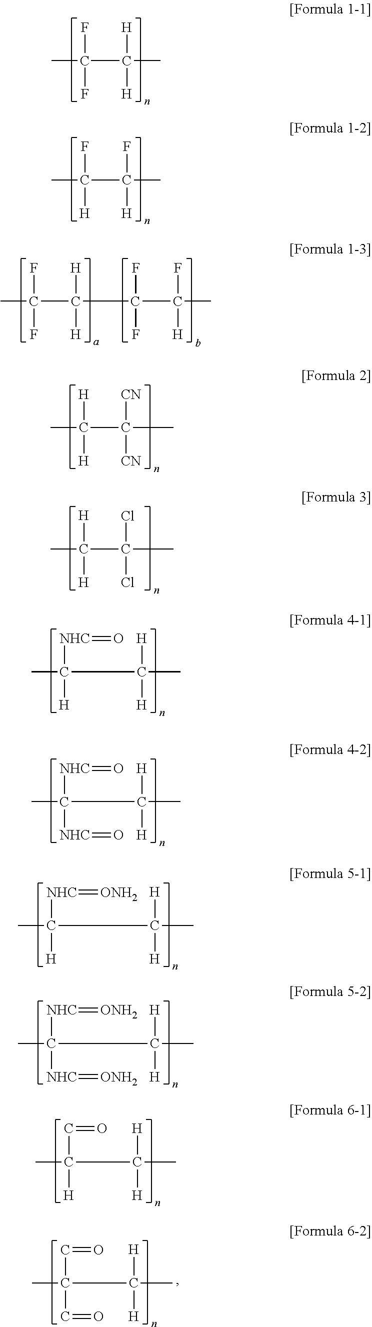
wherein in each of Formulas 1-1, 1-2 and 2 to 6-2, n is an integer of 100 to 20000,
wherein in Formula 1-3, a is a number of 0.7 to 0.8, b is a number of 0.2 to 0.3, and a summation of a and b is 1.

12. The display device according to claim 1, wherein the switchable reflective layer includes a first region and a second region, and
wherein the electroactive material pattern in the first region and the electroactive material pattern in the second region have a difference in at least one of a shape, a thickness, a width and a pitch.

13. The display device according to claim 12, wherein a light having a first wavelength range is reflected by the switchable reflective layer in the first region, and a light having a second wavelength range being different from the first wavelength range is reflected by the switchable reflective layer in the second region.

14. The display device according to claim 1, wherein the electrode layer includes a first electrode and a second electrode spaced apart from the first electrode.

15. The display device according to claim 14, wherein each of the first and second electrodes includes a transparent conductive material.

16. The display device according to claim 1, wherein the switchable reflective layer further includes an insulating layer covering the electrode layer and positioned under the electroactive material pattern.

17. The display device according to claim 1, wherein the switchable reflective layer further includes a base covering the display panel and positioned under the electrode layer.

18. The display device according to claim 1, wherein the display panel is an organic light emitting diode panel or a liquid crystal panel.
